(19) United States
(12) Patent Application Publication
(10) Pub. No.: US 2025/0260302 A1
(43) Pub. Date: Aug. 14, 2025

(54) CURRENT SENSING IN A MULTIPHASE POWER CONVERTER

(71) Applicant: TEXAS INSTRUMENTS INCORPORATED, Dallas, TX (US)

(72) Inventors: Laure Chevallier, Froges (FR); Riccardo Ruffo, Muenchen (DE)

(21) Appl. No.: 18/735,396

(22) Filed: Jun. 6, 2024

Related U.S. Application Data
(60) Provisional application No. 63/553,400, filed on Feb. 14, 2024.

(51) Int. Cl. H02M 1/00; G01R 19/165; G01R 19/25; H02M 3/157; H02M 3/158

(52) U.S. Cl. CPC H02M 1/0009; G01R 19/16528; G01R 19/25; H02M 3/157; H02M 3/1586

(57) ABSTRACT

A multiphase power converter includes a first and second phase circuits and a current sense circuit. The first phase circuit has a first input, a first output, and a first terminal. The first output is coupled to a positive voltage terminal, and the first terminal is coupled to a first negative voltage terminal. The second phase circuit has a second input, a second output, and a second terminal. The second input is coupled to the first input, the second output is coupled to the positive voltage terminal, and the second terminal is coupled to the first negative voltage terminal. The current sense circuit has first and second current sense terminals. The first current sense terminal is coupled to the first negative voltage terminal and the second current sense terminal is coupled to a second negative voltage terminal.

### CROSS-REFERENCE TO RELATED APPLICATIONS

This application claims priority to U.S. Provisional Application No. 63/553,400, filed Feb. 14, 2024, which is hereby incorporated by reference.

### BACKGROUND

A multiphase power converter (also referred to as an interleaved power converter) includes two or more phases coupled together in parallel. Examples of multiphase power converters include boost converters, buck converters, and so on. the current through phases should approximately match each other. If the current through each phase is not approximately balanced, heat generated by the phases will not be equally shared, thereby contributing to reduced efficiency and reliability.

### SUMMARY

In one example, a multiphase power converter includes a first and second phase circuits and a current sense circuit. The first phase circuit has a first input, a first output, and a first terminal. The first output is coupled to a positive voltage terminal, and the first terminal is coupled to a first negative voltage terminal. The second phase circuit has a second input, a second output, and a second terminal. The second input is coupled to the first input, the second output is coupled to the positive voltage terminal, and the second terminal is coupled to the first negative voltage terminal. The current sense circuit has first and second current sense terminals. The first current sense terminal is coupled to the first negative voltage terminal and the second current sense terminal is coupled to a second negative voltage terminal.

In another example, a multiphase power converter includes a first phase circuit having an input and an output, and a second phase circuit having an input coupled to the input of the first phase circuit and having an output coupled to the output of the first phase circuit. A first capacitor has first and second terminals. The first terminal of the first capacitor is coupled to the outputs of the first and second phase circuits. A second capacitor has first and second terminals. The first terminal of the second capacitor is coupled to the outputs of the first and second phase circuits. A resistor has first and second terminals, the first terminal of the resistor coupled to the second terminal of the first capacitor and the second terminal of the resistor coupled to second terminal of the second capacitor.

In yet another example, a circuit includes an analog-to-digital converter (ADC) having an analog input and a control input. A first comparator has first and second inputs and an output. The output of the first comparator is coupled to the control input. A second comparator has third and fourth inputs and an output. A first counter has an input and an output. The output of the first counter is coupled to the first and third inputs.

### BRIEF DESCRIPTION OF THE DRAWINGS

FIG. 1 is a schematic diagram of a multiphase power converter, in an example.

FIGS. 2-4 represent four different states of operation of the multiphase power converter, in examples.

FIG. 6 is a timing diagram illustrating example waveforms for inductor currents, sense current, and PWM carrier waves of the multiphase power converter, in an example.

FIG. 7 is a schematic diagram of the multiphase power converter including a damping circuit in a first location within the multiphase power converter, in an example.

FIG. 8 is a schematic diagram of the multiphase power converter including the damping circuit in a second location within the multiphase power converter, in another example

FIG. 9 is a block diagram of a PWM controller in the multiphase power converter, in an example.

FIG. 10 is a flow diagram illustrating the operation of the PWM controller, in an example.

### DETAILED DESCRIPTION

The same reference numbers or other reference designators are used in the drawings to designate the same or similar (either by function and/or structure) features.

Balancing the current between the phases of a multiphase power converter includes measuring the current in each phase. The multiphase power converter described herein implements current sensing that advantageously does not require multiple current sense circuits nor isolated circuits or devices for sensing current, e.g., isolated amplifiers, isolated Hall effect sensors for the current sense circuit.

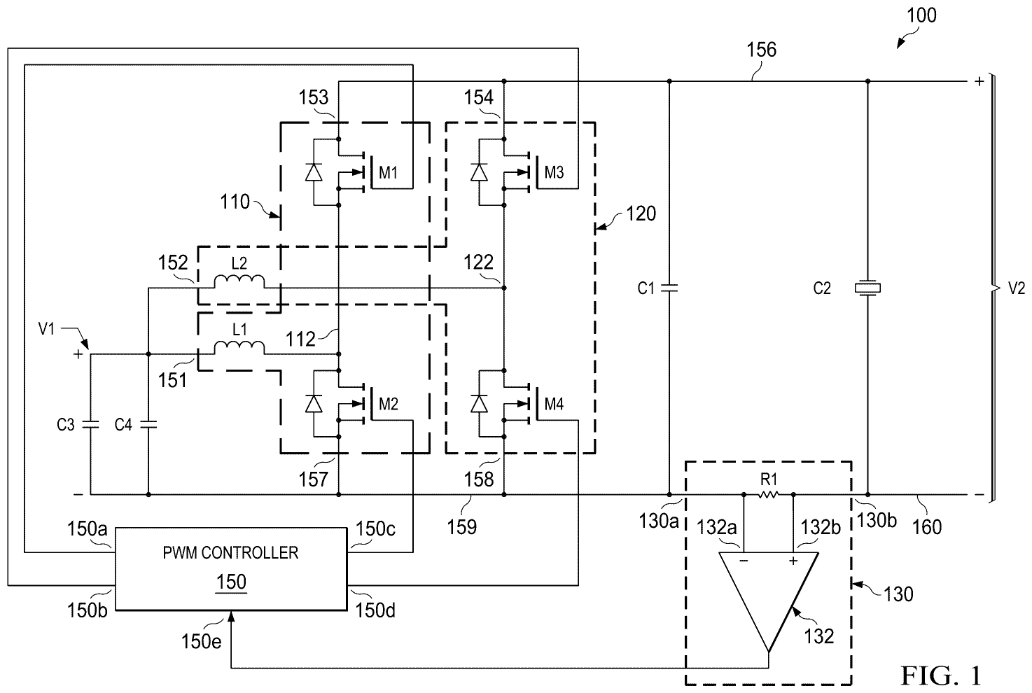

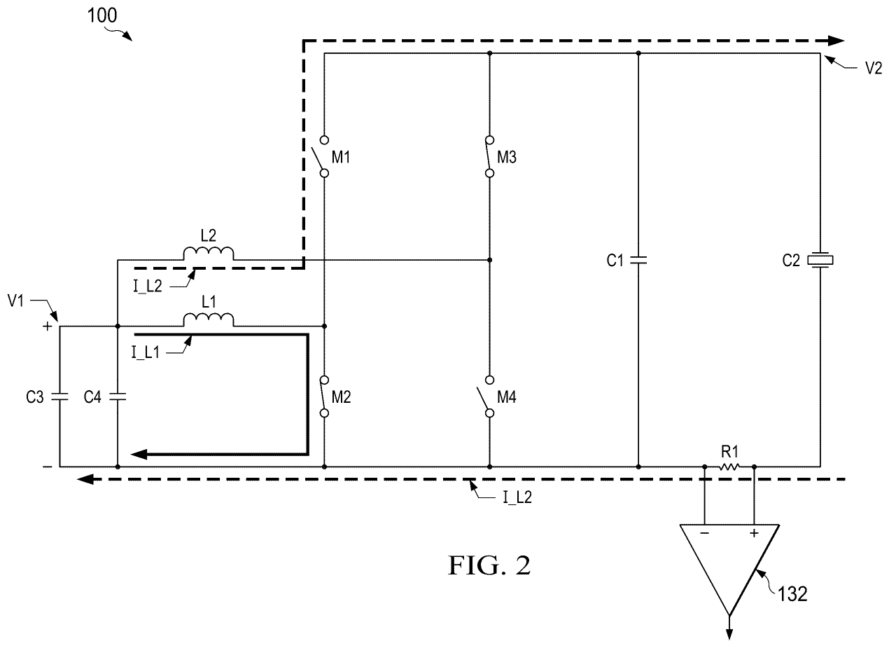

FIG. 1 is a schematic diagram of a multiphase power converter 100, in an example. In this example, multiphase power converter 100 includes two phases, but the principles described herein apply to any number of phases of a multiphase power converter. Multiphase power converter 100 includes phase circuits 110 and 120, capacitors C1, C2, C3, and C4, a pulse width modulation (PWM) controller 150, and a current sense circuit 130. In one example, transistors M1-M4, capacitors C1-C4, inductors L1 and L2, and PWM controller 150 are discrete components mounted on a printed circuit board (PCB).

Multiphase power converter 100 is a bidirectional power converter. For example, multiphase power converter 100 can receive a voltage V1 and produce a larger voltage V2 (boost converter), or receive a voltage V2 and produce a voltage V1 at a lower voltage level (buck converter). Phase circuits 110 and 120 have respective terminals 151 and 152 coupled together to receive or provide voltage V1. Phase circuits 110 and 120 also have respective terminals 153 and 154 coupled together and to a positive voltage terminal 156 to provide or receive voltage V2. Phase circuits 110 and 120 have respective terminals 157 and 158 coupled together at a negative voltage terminal 159. The terms “positive voltage rail” and “negative voltage rail” are relative terms meaning that the voltage on a positive supply voltage terminal is more positive than the voltage on a negative supply voltage terminal. The voltage of the negative supply voltage terminal may be earth ground or a voltage other than earth ground.

Capacitors C3 and C4 are coupled in parallel between inputs 151/152 and the negative supply voltage terminal. Current sense circuit 130 has terminals 130a and 130b and is coupled into the negative supply voltage terminal. Capacitor C1 has a terminal coupled to the positive voltage terminal 156 and a terminal coupled to the negative voltage terminal 159 and to terminal 130a of current sense circuit 130. Capacitor C2 has a terminal coupled to the positive voltage terminal 156 and a terminal coupled to terminal 130b of current sense circuit 130. Current sense circuit 130 includes a low resistance resistor R1 (e.g., 10 milliohms). Due to the low resistance of resistor R1, the voltage drop across resistor R1 is small enough that the connection of terminal 130b of current sense circuit 130 and capacitor C2 is also referred to herein as a negative voltage terminal 160. Current sense circuit 130 also includes an amplifier 132 which has positive and negative inputs 132a and 132b coupled to opposing terminals resistor R1. In another example, current sense circuit 130 includes a Hall effect sensor

Phase circuit 110 includes an inductor L1 and transistors M1 and M2. Phase circuit 120 includes an inductor L2 and transistors M3 and M4. In this example, transistors M1-M4 are n-channel field effect transistors (NFETs) but some or all of the transistors can be implemented as other types of transistors in other examples. The source of transistor M1 is coupled to the drain of transistor M2 at a switching terminal 112. One terminal of inductor L1 is coupled to input 151 and another terminal of inductor L1 is coupled to the switching terminal 112. The drain of transistor M1 is coupled to the output 153, and the source of transistor M2 is coupled to the negative voltage terminal 159. The configuration of phase circuit 120 is similar to that of phase circuit 110. The source of transistor M3 is coupled to the drain of transistor M4 at a switching terminal 122. One terminal of inductor L2 is coupled to input 152 and another terminal of inductor L2 is coupled to the switching terminal 122. The drain of transistor M3 is coupled to the output 154, and the source of transistor M4 is coupled to the negative voltage terminal 159.

PWM controller includes logic has outputs 150a, 150b, 150c, and 150d and an input 150e. Output 150a is coupled to the gate of transistor M1. Output 150b is coupled to the gate of transistor M3. Output 150c is coupled to the gate of transistor M2. Output 150d is coupled to the gate of transistor M4. In one example, PWM controller 150 includes digital circuit components such as logic gates, flip-flops, registers. In another example, PWM controller 150 includes a programmable logic circuit such as a microcontroller. Current sense circuit has an output 130c coupled to the output of amplifier 132. Output 130c is coupled to the input 150e of PWM controller 150.

As shown in FIG. 1, current sense circuit 130 is located in the negative voltage terminal of multiphase power converter 100. Other possible locations for the current sense circuit include, for example, locations adjacent (e.g., coupled to) inductors L1 and L2. For example, the current sense circuit 130 could be coupled between inductor L1 and switching terminal 112. However, locating the current sense circuit at that position in the circuit would mean including two current sense circuits-one connected to inductor L1 and another connected to inductor L2—thereby increasing the area of the multiphase power converter (e.g., the area of the PCB on which the components of the power converter are mounted), part count, and cost. Further, due to the relatively high voltages at the switching terminals 112 and 122, the amplifiers 132 within the respective current sense circuits 130 may need to be isolated amplifiers, or another type of isolated current sensor may be used such as a Hall effect sensor. Locating the current sense circuit 130 at the negative voltage terminal of multiphase power converter 100 between capacitors C1 and C2, as shown in FIG. 1, advantageously avoids the necessity of having two current sense circuits and avoids the amplifier 132 from being an isolated amplifier.

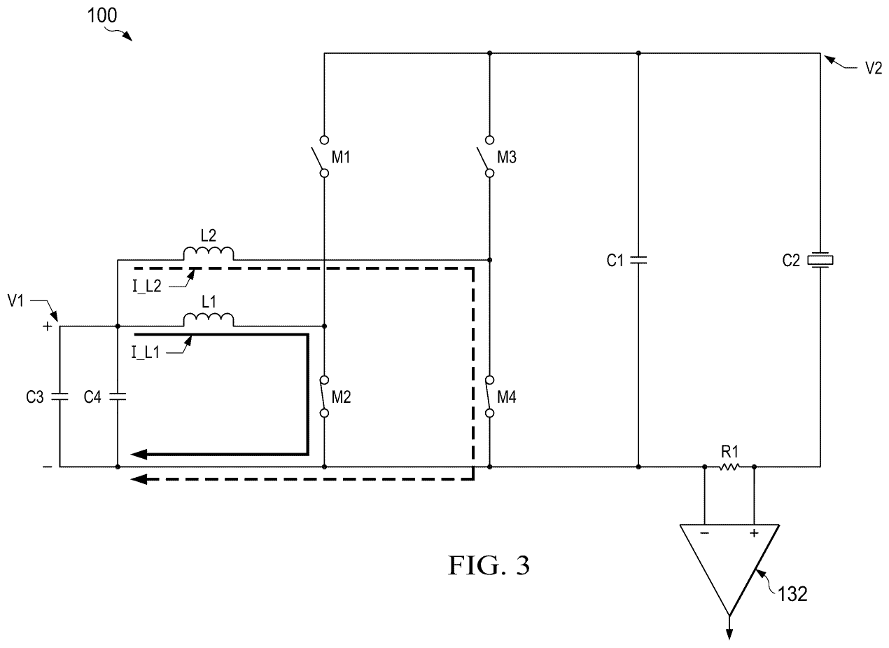

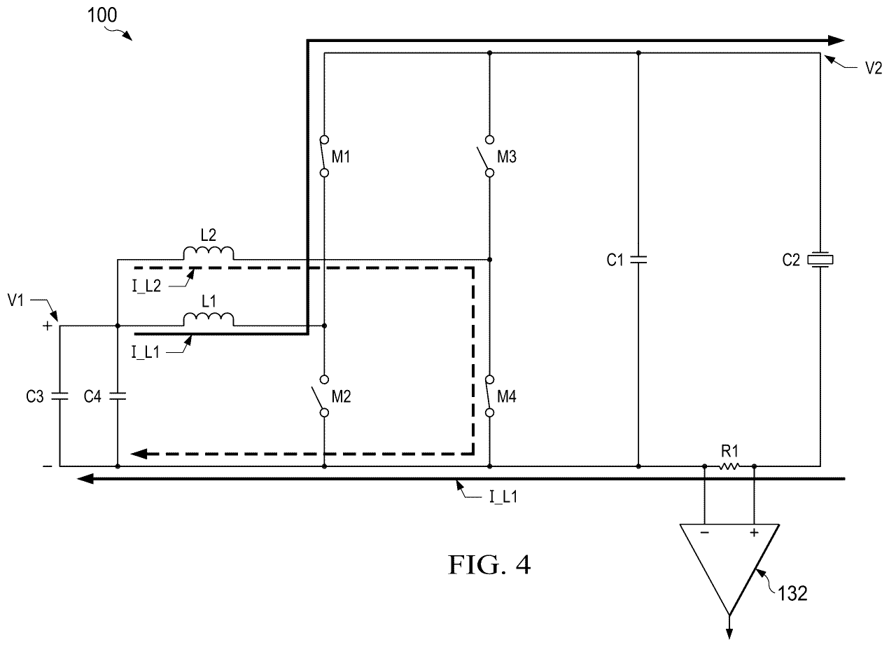

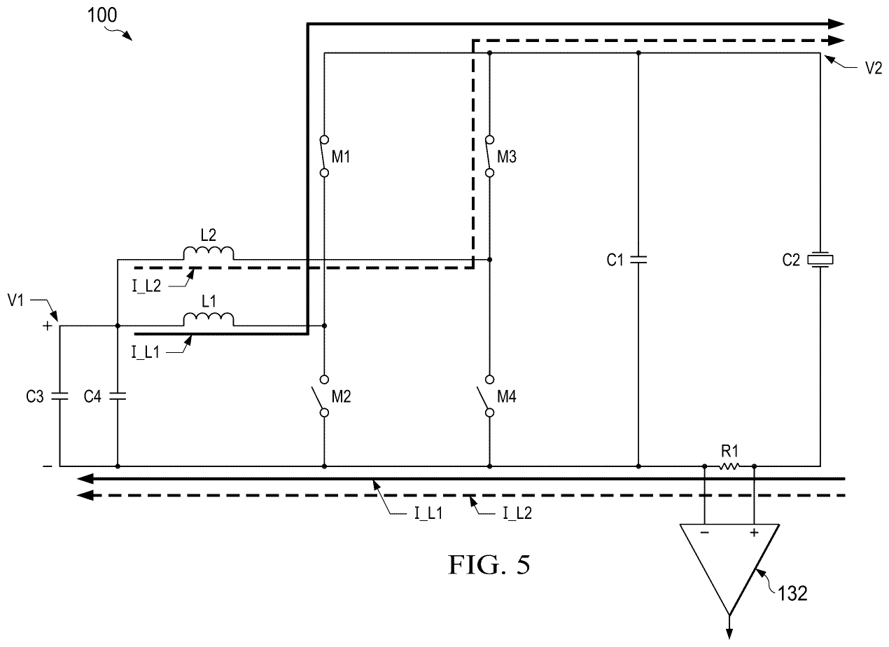

FIGS. 2-4 represent four different states of multiphase power converter 100. The difference in the four states are the on and off states of transistors M1-M4 (shown symbolically as switches in FIGS. 2-4). In FIG. 2, transistors M2 and M3 are on (closed) and transistors M1 and M4 are off (open). In FIG. 3, transistors M2 and M4 are on and transistors M1 and M3 are off. In FIG. 4, transistors M1 and M4 are on and transistors M2 and M3 are off. In FIG. 5, transistors M1 and M3 are on and transistors M2 and M4 are off. In FIGS. 2-4, the current through inductor L1 is current I_L1 and the current through inductor L2 is current I_L2.

In the states depicted in FIGS. 2 and 4, the current through resistor R1 is one or the other of current I_L1 or I_L2. In FIG. 2 with transistors M2 and M3 on and transistors M1 and M4 off, current I_L2 flows through inductor L2, through transistor M3 and back through resistor R1 and through capacitors C3 and C4 to inductor L2. In this state, current I_L1 circulates through inductor L1, transistor M2 and capacitors C3 and C4. Accordingly, the current through resistor R1 is equal to the current I_L2 of inductor L2.

In FIG. 3, with transistors M2 and M4 on, current I_L2 circulates through inductor L2, transistor M4, and capacitor C3 and C4. Similarly, current I_L1 circulates through inductor L1, transistor M2, and capacitor C3 and C4. Neither current I_L1 nor I_L2 flows through resistor R1 in this state.

In FIG. 4 with transistors M1 and M4 on and transistors M2 and M3 off, current I_L1 flows through inductor L1, through transistor M1 and back through resistor R1 and through capacitors C3 and C4 to inductor L1. In this state, current I_L2 circulates through inductor L2, transistor M4 and capacitors C3 and C4. Accordingly, the current through resistor R1 is equal to the current I_L1 of inductor L1.

In FIG. 5, with transistors M1 and M3 on, current I_L2 flows through inductor L2, transistor M3 and back through resistor R1 and capacitors C3 and C4. Similarly, current I_L1 flows through inductor L1, transistor M1 and back through resistor R1 and capacitors C3 and C4. Accordingly, the current through resistor R1 in this state is the sum of current I_L1 and IL2.

The states corresponding to FIGS. 2 and 4 are the states in which PWM controller 150 should obtain a current sense reading from amplifier 132. Obtaining a current sense reading when PWM controller 150 is operating transistors M1-M4 in the state corresponding to FIG. 3 is useless because neither inductor's current flows through resistor R1 in that state. Further, obtaining a current sense reading when PWM controller 150 is operating transistors M1-M4 in the state corresponding to FIG. 5 does not provide an indication of either inductor's individual current.

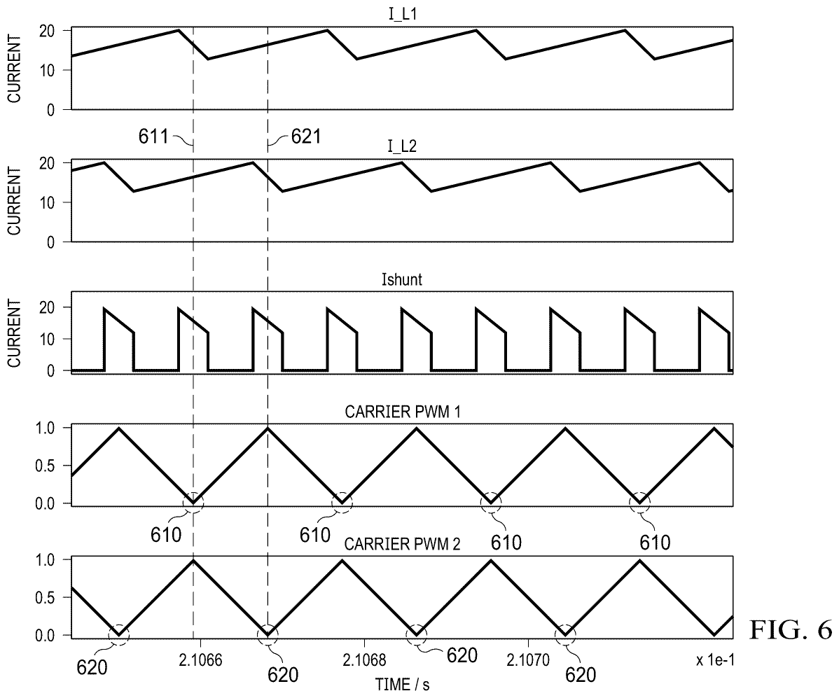

FIG. 6 is a timing diagram illustrating example waveforms for current I_L1 through inductor L1, current I_L2 through inductor L2 current Ishunt (current through resistor R1), carrier PWM 1 (carrier waveform for phase circuit 110), and carrier PWM 2 (carrier waveform for phase circuit 120). During each PWM switching cycle for phase circuit 110, the current I_L1 through inductor L1 increases during the state corresponding to FIGS. 2 and 3 and then, following a short time period spent in the state of FIG. 3, decreases during the state corresponding to FIGS. 4 and 5. Similarly, during each PWM switching cycle for phase circuit 120, the current I_L2 through inductor L2 increases during the state corresponding to FIGS. 3 and 4 and then decreases during the states corresponding to FIGS. 5 and 2.

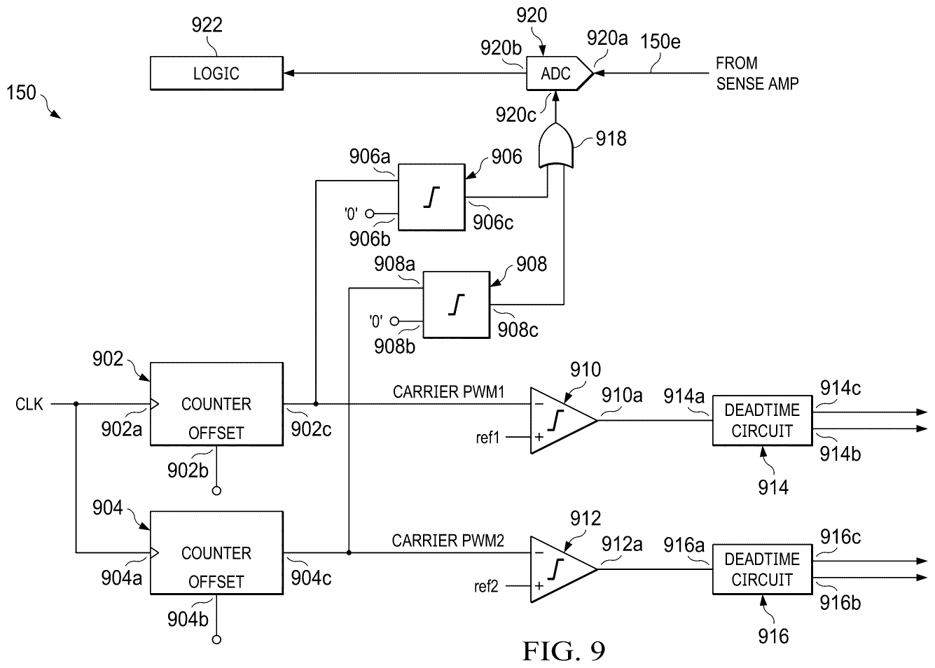

The carrier PWM 1 and carrier PWM 2 signals are generated internally to PWM controller 150, as described below and shown in FIG. 9. PWM controller 150 obtains the current sense value from current sense circuit 130 when each carrier PWM 1, 2 signal reaches its lowest value or is within a threshold of the lowest value. Accordingly, at time points 610, PWM controller 150 obtains a current sense value from current sense circuit 130. The current sense value at that point in time corresponds to the state in which current I_L1 is decreasing as indicated by dashed line 611 and current Ishunt (current of resistor R1) is the current I_L1 of inductor L1. At time points 620, PWM controller 150 obtains a current sense value from current sense circuit 130. The current sense value at time point 620 corresponds to the state in which current I_L2 is decreasing as indicated by dashed line 621 and current Ishunt is the current I_L2 of inductor L2.

A purpose of capacitor C1 in FIG. 1 is to reduce the parasitic inductance in the conductors (e.g., copper traces on a circuit board) between the outputs 153, 154 and terminals 157, 158 of phase circuits 110 and 120 and the load powered by multiphase power converter 100. Capacitor C1 may be a ceramic capacitor and located on the circuit board close to the phase circuits 110, 120. By reducing the parasitic inductance, capacitor C1 helps to reduce the peak voltage of Vout and reduce the voltage across each transistor during switching. Capacitor C2 may be a thin film capacitor and functions to reduce the ripple current and voltage ripple at the output of multiphase power converter 100. A downside of having both capacitors C1 and C2 is a resonance that may form between the two capacitors based on the equivalent series inductance of capacitors C1 and C2 and the parasitic inductance of the traces connecting capacitor C1 to capacitor C2. The resonance manifests itself as ringing in the output current each time the transistors change state. Because current sense circuit 130 is positioned between capacitors C1 and C2, current sense circuit 130 also detects the ringing which (a) may make less accurate a determination of the current through either of the phase circuits 110 and 120 and (b) may trigger false positives of overcurrent detection.

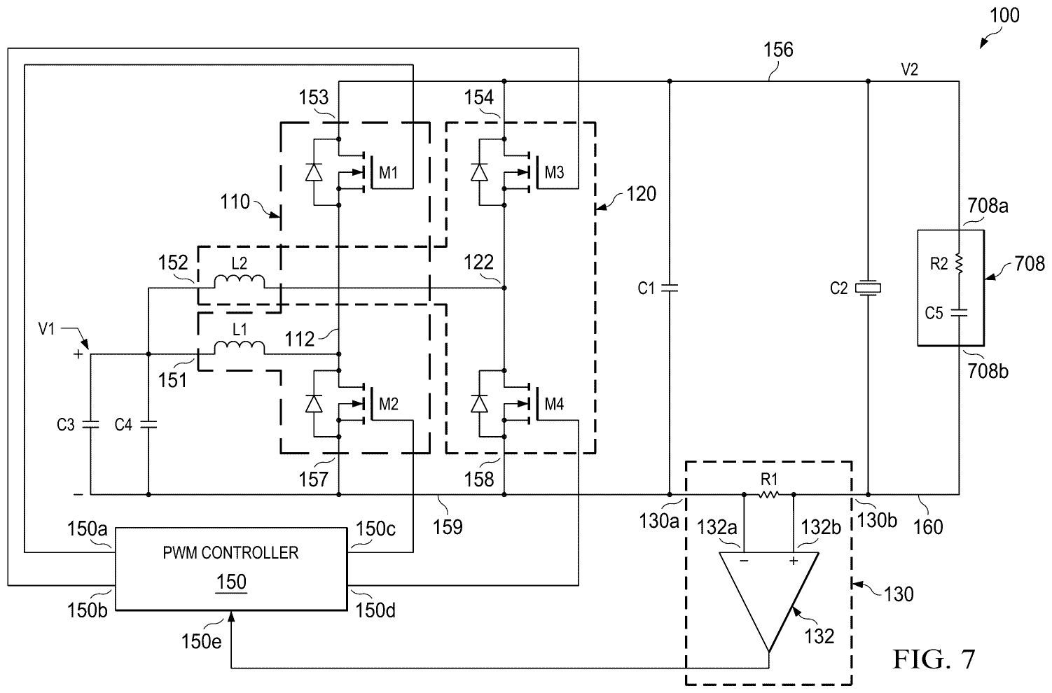

FIG. 7 is a schematic diagram of multiphase power converter 100 similar to that of FIG. 1. Multiphase power converter 100 in FIG. 7, however, includes a damping circuit 708. In one example, damping circuit includes a resistor R2 coupled in series with a capacitor C5. Terminal 708a of damping circuit 708 is coupled to the positive voltage terminal 156 and another terminal 708b of damping circuit 708 is coupled to the negative voltage terminal 160 and terminal 130b of current sense circuit 130. In one example, the capacitance of capacitor C5 is set approximately equal to the capacitance of capacitor C1, and the resistance of resistor R2 is set approximately equal to:

$$R 2 = \sqrt{\frac{{L}_{σ}}{C 1}} \qquad Eq . ( 1 )$$

where L_{σ} is the sum of the parasitic impedances of capacitors C1 and C2 and the parasitic inductance of the traces connecting capacitor C1 to C2 Damping circuit attenuates the ringing in the current through resistor R1, which otherwise would be present absent the damping circuit.

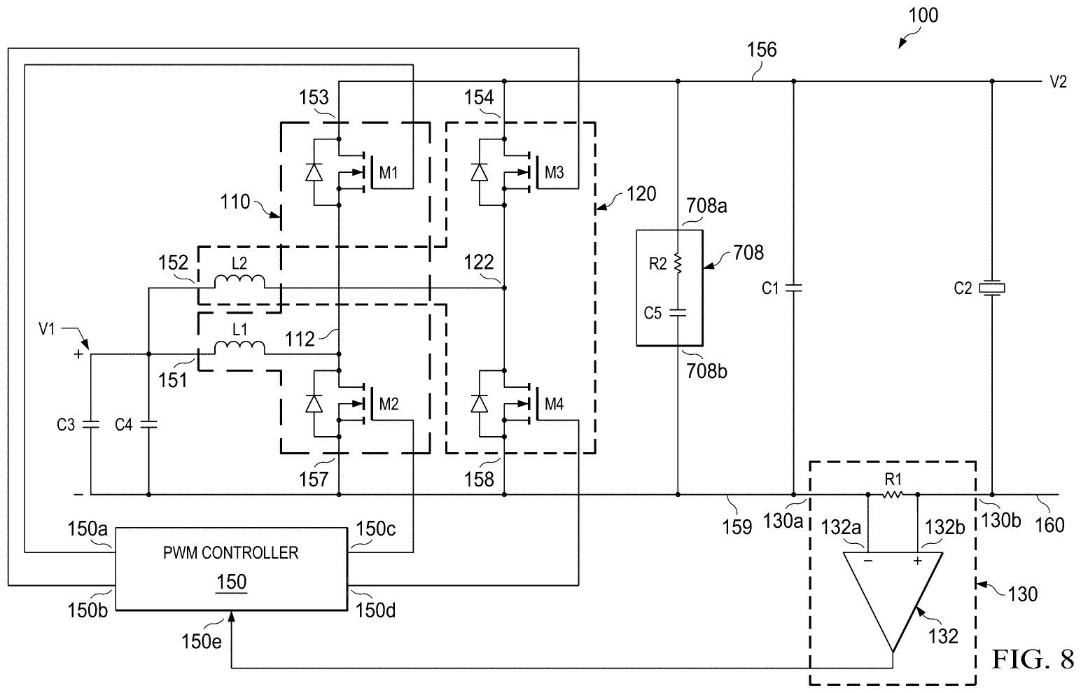

FIG. 8 is a schematic diagram of multiphase power converter 100 in another example. The example of FIG. 8 is similar to that of FIG. 7. A difference is the location of damping circuit 708. In FIG. 8, terminal 708a of damping circuit 708 is coupled to positive voltage terminal 156 and terminal 708b is coupled to negative voltage terminal 159 and to terminal 130a of current sense circuit 130. The example damping circuit 708 in FIG. 8 also is a series combination of resistor R2 and capacitor C5, whose values can be set as per the description above.

FIG. 9 is a block diagram of PWM controller 150, in an example. PWM controller 150 includes counters 902 and 904, comparators 906, 908, 910, and 912, deadtime circuits 914 and 916, OR gate 918, an analog-to-digital converter (ADC), and logic 922. Counter 902 has a clock input 902a, an offset input 902b, and an output 902c. Counter 904 has a clock input 904a, an offset input 904b, and an output 904c. A clock signal, CLK, is provided to the clock inputs 902a and 904a of counters 902 and 904. The output count values from counters 902 and 904 are Carrier PWM 1 and Carrier PWM 2, respectively. In one example, counters 902 and 904 are digital counters that count up to a first value and then count down to a second value, back up to the first value and so on. The offset inputs 902b and 904b receive respective fixed offset values. In one example, the frequency of clock signal CLK is 100 MHz and the frequency of Carrier PWM 1 and Carrier PWM 2 is 10 KHz. Each counter 902 and 904 counts up from 0 to 5000, down from 5000 to 0, and so on. Based on the offset values provided to offset inputs 902b and 904, while counter 902 counts up from 0 to 5000, counter 904 counts down from 5000 to 0.

The output 902c of counter 902 is coupled to an input 906a of comparator 906 and to the positive input of comparator 910. The output 904c of counter 904 is coupled to input 908a of comparator 908 and to the positive input of comparator 912. Each negative input of comparators 910 and 912 receives a reference signal ref1 and ref2, respectively. Reference signals ref1 and ref2 are indicative of the duty cycles of the respective phase circuits 110 and 120. The output 910a of comparator 910 is coupled to an input 914a of deadtime circuit 914. Deadtime circuit 914 produces a complementary pair of output signals at its outputs 914b and 914c to drive respective transistors M1 and M2 while ensuring a suitable deadtime between one transistor (M1, M2) turning off and the other transistor (M2, M1) turning on. Comparator 910 compares the signal Carrier PWM 1 to the reference signal ref1. The signals at outputs 914b and 914c for phase circuit 110 are provided by deadtime circuit 914 to drivers (not shown) to turn on and off transistors M1 and M2 of phase circuit 110. The output 912a of comparator 912 is coupled to an input 916a of deadtime circuit 916. Deadtime circuit 916 produces a complementary pair of output signals at its outputs 916b and 916c to drive respective transistors M3 and M4 while ensuring a suitable deadtime between one transistor (M3, M4) turning off and the other transistor (M4, M3) turning on. Comparator 912 compares the signal Carrier PWM 2 to the reference signal ref2. The signals at outputs 916b and 916c for phase circuit 120 are provided by deadtime circuit 916 to drivers (not shown) to turn on and off transistors M3 and M4 of phase circuit 120.

Comparator 906 compares Carrier PWM 1 to a reference value (e.g., 0) provided to its input 906b and determines when the Carrier PWM 1 value is equal to the reference value. Similarly, comparator 908 compares Carrier PWM 2 to a reference value (e.g., 0) provided to its input 908b and determines when the Carrier PWM 2 value is equal to the reference value. The outputs 906c and 908c of comparators 906 and 908, respectively, are provided to inputs of OR gate 918. ADC 1020 as an analog input 920a, a digital output 920b, and a control input 920c. The signal from the current sense circuit 130 is provided to analog input 920a of ADC 920. OR gate 918 logically ORs the output signals from comparators 906 and 908. Each comparator 906, 908 generates its output signal to be logic high when its respective Carrier PWM 1, 2 reaches the threshold. The output signal from OR gate is provided to the control 920c of ADC 920. When the signal at the control input 920c is logic high, the ADC 920 is activated/enabled to convert the analog input signal from current sense circuit 130 to a digital output value provided to logic 922. Logic 922 may include logic gates, flip-flops, etc. configured to determine whether the current through the phase circuits 110 and 120 are balanced. In one example, if the currents through phase circuits 110 and 120 are not balanced, then the reference signals ref1 and/or ref2 can be adjusted within PWM controller 150 to adjust the duty cycle of the transistors of one phase circuit relative to the other to better balance the current.

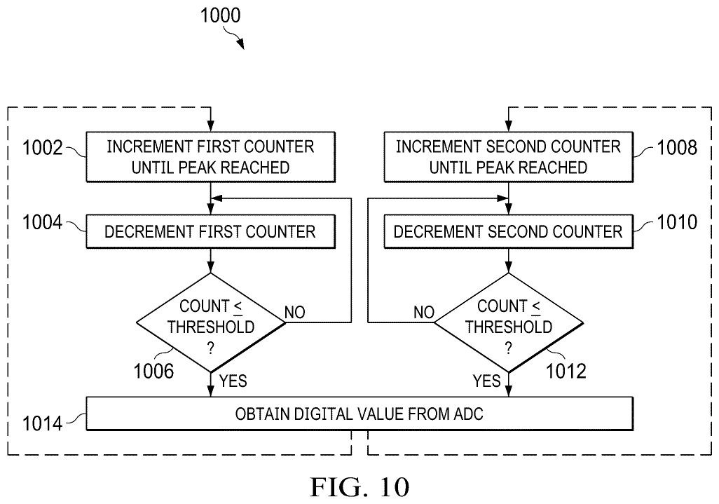

FIG. 10 is a flow diagram 1000 illustrating the operation of PWM controller 150. Operations 1002, 1004, and 1006 are performed in parallel with operations 1008, 1010, and 1012. At operation 1002, counter 902 increments its output value until a peak value is reached. Then, at operation 1004, counter 902 begins decrementing its output value. At operation 1006, the output value from counter 902 is compared to a threshold (e.g., 0). If the output value from counter 902 has not reached the threshold, then control loops back to operation 1004. Otherwise, operation 1014 is performed. Similarly, at operation 1008, counter 904 increments its output value until a peak value is reached. Then, at operation 1010, counter 904 begins decrementing its output value. At operation 1012, the output value from counter 904 is compared to a threshold (e.g., 0). If the output value from counter 904 has not reached the threshold, then control loops back to operation 1010. Otherwise, operation 1014 is performed. At operation 1014, a digital value is obtained from ADC 920 by, for example, OR gate 918 generating a signal to control input 920c to activate/enable ADC 920 to generate a digital output value based on the analog input signal at input 150e.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A multiphase power converter, comprising:
a first phase circuit having a first input, a first output, and a first terminal, the first output coupled to a positive voltage terminal, and the first terminal coupled to a first negative voltage terminal;
a second phase circuit having a second input, a second output, and a second terminal, the second input coupled to the first input, the second output coupled to the positive voltage terminal, and the second terminal coupled to the first negative voltage terminal; and
a current sense circuit having first and second current sense terminals, the first current sense terminal coupled to the first negative voltage terminal and the second current sense terminal coupled to a second negative voltage terminal.

2. The multiphase power converter of claim 1, further comprising:
a first capacitor having first and second capacitor terminals, the first capacitor terminal coupled to the positive voltage terminal, and the second capacitor terminal coupled to the first current sense terminal; and
a second capacitor having third and fourth capacitor terminals, the third capacitor terminal coupled to the positive voltage terminal, and the fourth capacitor terminal coupled to the second current sense terminal.

3. The multiphase power converter of claim 2, further comprising a damping circuit having first and second damping circuit terminals, the first damping circuit terminal coupled to the positive voltage terminal.

4. The multiphase power converter of claim 3, wherein the damping circuit includes a resistor coupled in series with a third capacitor.

5. The multiphase power converter of claim 3, wherein the second damping circuit terminal is coupled to the second current sense terminal.

6. The multiphase power converter of claim 3, wherein the second damping circuit terminal is coupled to the first current sense terminal.

7. The multiphase power converter of claim 1, wherein the current sense circuit includes a resistor having a first resistor terminal coupled to the first current sense terminal and a second resistor terminal coupled to the second current sense terminal.

8. The multiphase power converter of claim 1, further comprising a controller configured to generate a carrier signal, determine that a magnitude of the carrier signal has fallen below a threshold, and convert an analog signal from the current sense circuit to a digital signal.

9. The multiphase power converter of claim 1, wherein the current sense circuit has an output, the multiphase power converter further comprises a controller including:
an analog-to-digital converter (ADC) having an analog input and a control input, the analog input coupled to the output of the current sense circuit;
a comparator having a first input, a second input, and an output, the first input of the comparator configured to receive a threshold value, and the output of the comparator coupled to the control input of the ADC; and
a counter having an output coupled to the second input of the comparator.

10. A multiphase power converter, comprising:
a first phase circuit having an input and an output;
a second phase circuit having an input coupled to the input of the first phase circuit and having an output coupled to the output of the first phase circuit;
a first capacitor having first and second terminals, the first terminal coupled to the outputs of the first and second phase circuits;
a second capacitor having first and second terminals, the first terminal of the second capacitor coupled to the outputs of the first and second phase circuits; and
a resistor having first and second terminals, the first terminal of the resistor coupled to the second terminal of the first capacitor and the second terminal of the resistor coupled to second terminal of the second capacitor.

11. The multiphase power converter of claim 10, further comprising a damping circuit having first and second terminals, the first terminal of the damping circuit coupled to the first terminals of the first and second capacitors.

12. The multiphase power converter of claim 11, wherein the resistor is a first resistor, and wherein the damping circuit includes a second resistor coupled in series with a third capacitor.

13. The multiphase power converter of claim 11, wherein the second terminal of the damping circuit is coupled to the second terminal of the first capacitor.

14. The multiphase power converter of claim 11, wherein the second terminal of the damping circuit is coupled to the second terminal of the second capacitor.

15. The multiphase power converter of claim 10, further comprising:
an amplifier coupled to the resistor and having an output; and
a controller configured to generate a carrier signal, determine that a magnitude of the carrier signal equals or is below a threshold, and convert an analog signal from the output of the amplifier to a digital signal.

16. The multiphase power converter of claim 10, further comprising an amplifier coupled to the resistor and having an output, the multiphase power converter further comprises a controller including:
an analog-to-digital converter (ADC) having an analog input and a control input, the analog input coupled to the output of the amplifier;
a comparator having a first input, a second input, and an output, the first input of the comparator configured to receive a threshold voltage, and the output of the comparator coupled to the control input of the ADC; and
a counter having an output coupled to the second input of the comparator.

17. A circuit, comprising:
an analog-to-digital converter (ADC) having an analog input and a control input;
a first comparator having first and second inputs and an output, the output coupled to the control input;
a second comparator having third and fourth inputs and an output; and
a first counter having an input and an output, the output coupled to the first and third inputs.

18. The circuit of claim 17, further comprising:
a third comparator having fifth and sixth inputs and an output, the output of the third comparator coupled to the control input;
a fourth comparator having seventh and eighth inputs and an output; and
a second counter having an input and an output, the output of the second counter coupled to the fifth and sixth inputs.

19. The circuit of claim 18, wherein the inputs of the first and second counters are configured to receive a clock signal.

20. The circuit of claim 18, wherein the ADC has a digital output and is configured to generate a digital output signal at the digital output in response to a signal at its control input.
